(19) United States
(12) Patent Application Publication
(10) Pub. No.: US 2026/0026315 A1
(43) Pub. Date: Jan. 22, 2026

(54) SACRIFICIAL PAD DESIGN FOR SEMICONDUCTOR DEVICE

(71) Applicant: Taiwan Semiconductor Manufacturing Co., Ltd., Hsinchu (TW)

(72) Inventors: Jun Yi Wu, Miaoli County (TW); Ting Hao Kuo, Hsinchu (TW); Yu-Chih Huang, Hsinchu (TW); Yu-Chia Lai, Zhunan Township (TW); Chen-Shien Chen, Zhubei City (TW)

(21) Appl. No.: 18/955,154

(22) Filed: Nov. 21, 2024

Related U.S. Application Data
(60) Provisional application No. 63/672,754, filed on Jul. 18, 2024.

(51) Int. Cl. H01L 21/66; H01L 21/768; H01L 23/00; H01L 23/31; H01L 23/498

(52) U.S. Cl. CPC H01L 22/32; H01L 21/76898; H01L 22/14; H01L 22/22; H01L 23/3128; H01L 23/49827; H01L 24/03; H01L 24/05; H01L 24/08; H01L 2224/03001; H01L 2224/05571; H01L 2224/05573; H01L 2224/08146; H01L 2224/08235; H01L 2924/35121

(57) ABSTRACT

A method of forming a semiconductor device includes: forming a conductive pad over and electrically coupled to an interconnect structure, where the interconnect structure is disposed over a substrate and electrically coupled to electrical components formed on the substrate; forming a passivation layer over the conductive pad and the interconnect structure; and forming a sacrificial test structure over the passivation layer and electrically coupled to the conductive pad, where the sacrificial test structure includes a sacrificial pad extending along an upper surface of the passivation layer distal from the substrate, and includes a sacrificial via extending into the passivation layer and contacting the conductive pad.

### PRIORITY CLAIM AND CROSS-REFERENCE

This application claims priority to and the benefit of U.S. Application No. 63/672,754, filed Jul. 18, 2024 and entitled “Sacrificial Pad Design to Enhance SoIC Yield,” which application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example is the System on Integrated Chips (SoIC) technology, which is a three-dimensional (3D) inter-chip stacking technology that integrates active and passive chips into a single System on Chip (SoC) system. The SoIC platform uses front-end technologies and precision methodologies from silicon fabs to stack chips in 3D. The SoIC platform allows for the integration of known good dies (KGDs) with different chip sizes, functionalities, and wafer node technologies. The resulting structure enables ultra-high-density vertical stacking to achieve high performance, low power, and low resistance-inductance-capacitance (RLC). These packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 4, 5, 6, 7, 8, and 9 illustrate various views of a semiconductor device at various stages of manufacturing, in accordance with an embodiment.

FIG. 10 illustrates a cross-sectional view of a semiconductor device, in accordance with another embodiment.

FIGS. 11A and 11B illustrate various views of a semiconductor structure, in accordance an embodiment.

FIG. 12 illustrates a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals in the various examples. Throughout the description, unless otherwise specified, the same or similar reference numerals in different figures refer to the same or similar component formed by a same or similar method using a same or similar material(s).

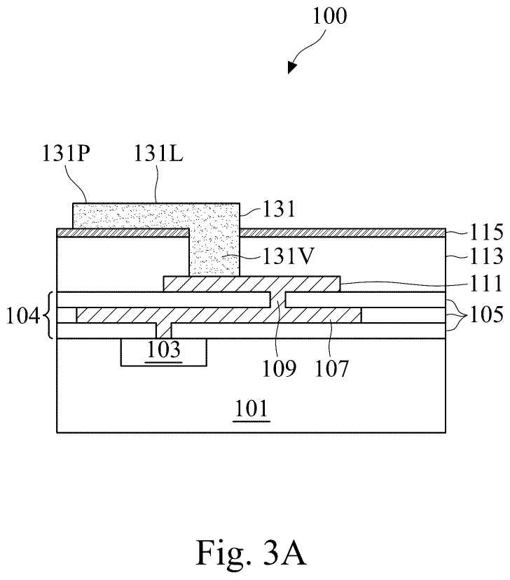

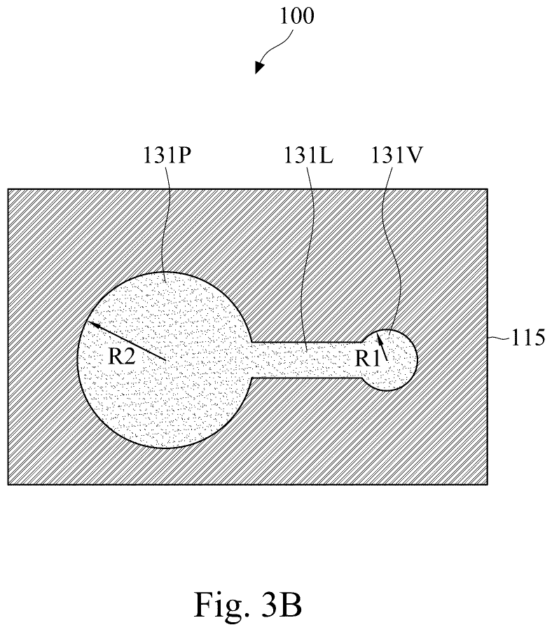

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In the discussion herein, figures with the same numeral but different letters (e.g., FIGS. 3A and 3B) illustrate various views of the same structure at a same manufacturing stage.

In some embodiments, during the fabrication process of a semiconductor die, a sacrificial test structure is formed over and electrically coupled to a conductive pad of the semiconductor die. The sacrificial test structure may be formed using, e.g., a solder material. During wafer testing, the test probe contacts the sacrificial test structure instead of the conductive pad of the die, thus avoiding scratching the conductive pad and forming a probe mark on the conductive pad. The sacrificial test structure is removed after the wafer testing. The probe mark, if formed, reduces the flatness (e.g., planarity) of the surface of the conductive pad, and may increase the risk of delamination for a dielectric layer formed subsequently on the conductive pad. The present disclosure, by using the sacrificial test structure for wafer testing, avoids the probe mark, and therefore, reduces the risk of delamination of the dielectric layer.

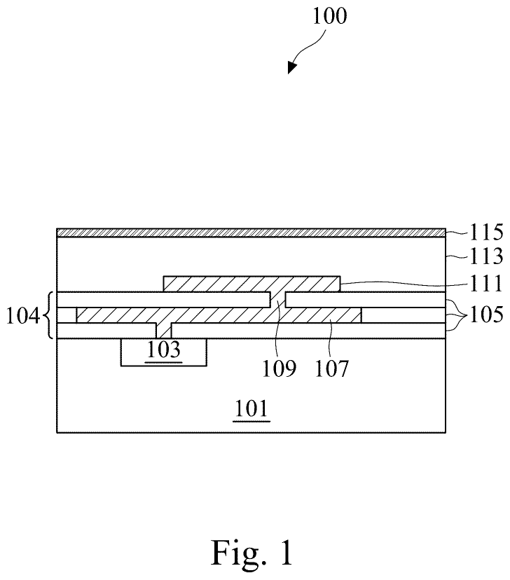

FIGS. 1, 2, 3A, 3B, 4, 5, 6, 7, 8, and 9 illustrate various views (e.g., cross-sectional view, top view) of a semiconductor device 100 at various stages of manufacturing, in accordance with an embodiment. In the illustrated embodiment, the semiconductor device 100 is a semiconductor die, and therefore, may also be referred to as a semiconductor die 100, or a die 100.

FIG. 1 illustrates a cross-sectional view of the semiconductor device 100 at an early stage of manufacturing. Note that for simplicity, not all features of the semiconductor device 100 are illustrated, and FIG. 1 (and subsequently figures) may illustrate only a portion the semiconductor device 100.

As illustrated in FIG. 1, the semiconductor device 100 includes a substrate 101, electrical components 103 formed on or in the substrate 101, and an interconnect structure 104 over the substrate 101. In addition, FIG. 1 illustrates conductive pads 111 over the interconnect structure 104, a passivation layer 113 over the conductive pads 111 and the interconnect structure 104, and an etch stop layer (ESL) 115 over the passivation layer 113. In the discussion herein, unless otherwise specified, the word “conductive” used in phrases such as “conductive pads,” “conductive material” or “conductive features” means electrically conductive (e.g., instead of thermally conductive).

The substrate 101 of the die 100 may be a semiconductor substrate (e.g., silicon substrate), doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The electrical components 103 of the die 100 comprise a wide variety of active devices (e.g., transistors) and/or passive devices (e.g., capacitors, resistors, inductors), and the like. The electrical components 103 of the die 100 may be formed using any suitable methods either within or on the substrate 101 of the die 100.

The interconnect structure 104 of the die 100 comprises one or more metallization layers (e.g., copper layers such as conductive lines 107 and vias 109) formed in one or more dielectric layers 105 (e.g., silicon oxide), and is used to connect the various electrical components 103 to form functional circuitry. The number of the dielectric layers 105 and the number of the metallization layers shown in FIG. 1 for the interconnect structure 104 are for illustration purpose and are not limiting.

In the example of FIG. 1, conductive pads 111 (may also be referred to as contact pads) are formed over the interconnect structure 104 and are electrically coupled to conductive features (e.g., in the topmost metallization layer) of the interconnect structure 104. The conductive pads 111 may be formed of aluminum, but other materials, such as copper, may alternatively be used.

The passivation layer 113 is formed over the conductive pads 111 and the interconnect structure 104 in order to provide a degree of protection for the structures of the die 100. The passivation layer 113 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The passivation layer may be formed through a process such as chemical vapor deposition (CVD), although any suitable process may be utilized.

The ESL 115 is formed over the passivation layer 113. In some embodiments, the ESL 115 is formed of a suitable material such as silicon nitride (e.g., SiN), silicon carbide (e.g., SiC), silicon carbonitride (e.g., SiCN), silicon oxynitride (SiON), or the like, and may be formed by a suitable formation method, such as physical vapor deposition (PVD), CVD, plasma-enhanced CVD (PECVD), or the like. The ESL 115 is used to protect the underlying structures and may be used to provide a control point for a subsequent etching process, in some embodiments.

In semiconductor device manufacturing, typically a plurality of dies (e.g., 100) are formed on a same wafer (e.g., a silicon wafer). The plurality of dies are separated into individual dies by a dicing process performed later. Therefore, the die 100 shown in FIGS. 1-9 may correspond to one of the dies formed on a wafer. For example, the substrate 101 may be a portion of the wafer (e.g., a silicon wafer).

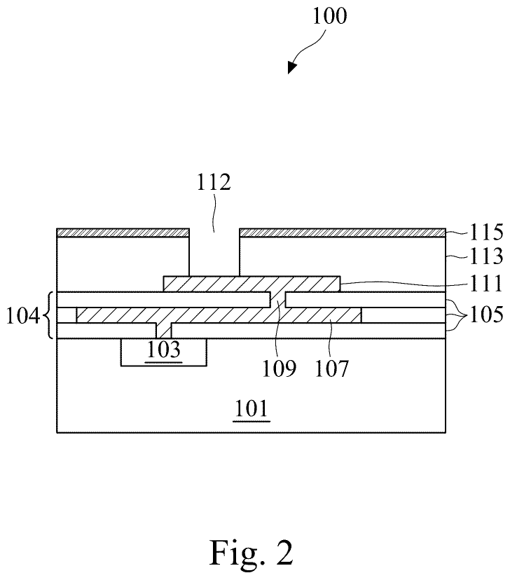

Next, in FIG. 2, openings 112 are formed that extend through the ESL 115 and the passivation layer 113 to expose the conductive pads 111. In some embodiments, an anisotropic etching process, such as a plasma etching process, is performed to form the openings 112.

During semiconductor device fabrication, after the conductive pads 111 of the semiconductor dies 100 are formed, wafer testing (also referred to as circuit probe (CP) test) is performed for the dies on the wafer to identify the known good dies (KGDs). During wafer testing, the dies 100 on the wafer are tested for functional defects by applying test patterns to the dies 100. The wafer testing is typically performed by a test equipment called a wafer prober. A wafer prober is a machine used for integrated circuits verification against designed functionality. In some embodiments, for electrical testing of the dies 100, a set of microscopic contacts or probes of the wafer prober are held in contact with the conductive pads 111 of the dies 100 during the wafer testing. However, the probes may scratch the surfaces of the conductive pads 111 and cause probe marks (e.g., dents) at the surfaces of the conductive pads 111. The depth of the probe marks may be larger than 2 μm. The probe marks reduce the flatness (e.g., planarity) of the surfaces of the conductive pads 111. In subsequent processing, the openings 112 are filled by a dielectric material. The reduced surface flatness of the conductive pads 111 may increase the risk of delamination of the dielectric material, and may cause device failure.

To avoid the scratching of the conductive pads 111 by the probes of the wafer prober during wafer testing, the presently disclosure discloses a sacrificial test structure 131 that includes a sacrificial pad 131P. Each sacrificial pad 131P is electrically coupled to a respective conductive pad 111. During wafer testing, the probes are held in contact with the sacrificial pads 131P instead of the conductive pads 111. Therefore, scratching of the conductive pads 111 is avoided. The sacrificial test structures 131 are removed after wafer testing. Details are discussed hereinafter.

Next, in FIG. 3A, sacrificial test structures 131 are formed over the ESL 115 and electrically coupled to respective conductive pads 111. In the example of FIG. 3A, each sacrificial test structure 131 includes a sacrificial pad 131P extending along the upper surface of the ESL 115, a sacrificial via 131V extending into the passivation layer 113 and contacting the underlying conductive pad 111, and a sacrificial line 131L extending along the upper surface of the ESL 115 and connecting the sacrificial pad 131P with the sacrificial via 131V.

FIG. 3B illustrates a top view of the semiconductor device 100 of FIG. 3A. In FIG. 3B, the top view of the sacrificial via 131V has a first circular shape with a radius R₁, and the top view of the sacrificial pad 131P have a second circular shape with a radium R₂, where R₂>R₁. In other words, in the top view, the area (e.g., surface area) of the sacrificial pad 131P is larger than that of the sacrificial via 131V. The larger area of the sacrificial pad 131P makes it easier for testing of the die 100. The shape of the sacrificial pad 131P and the shape of the sacrificial via 131V illustrated in FIG. 3B are merely non-limiting examples, other shapes (e.g., oval shape, rectangular shape, or the like) are possible and are fully intended to be included within the scope of the present disclosure.

In some embodiments, the sacrificial test structures 131 are formed by: forming a solder material in the openings 112 and over the upper surface of the ESL 115, where the solder material in the openings 112 forms the sacrificial vias 131V; and patterning the solder material disposed along the upper surface of the ESL 115 to form the sacrificial pads 131P and the sacrificial lines 131L.

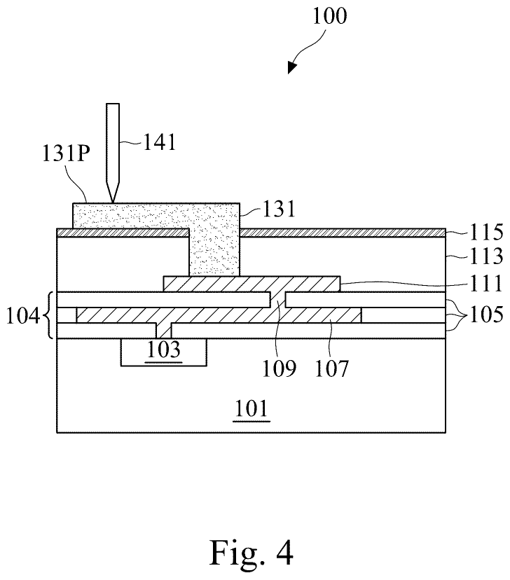

FIG. 4 shows the die 100 during wafer testing. A probe 141 of the wafer prober is held in contact with the sacrificial pad 131P during the wafer testing. Dies 100 that pass the wafer testing are identified as the known good dies (KGDs). After a subsequent dicing process, the KGDs are used to form semiconductor structures, such as SoIC devices.

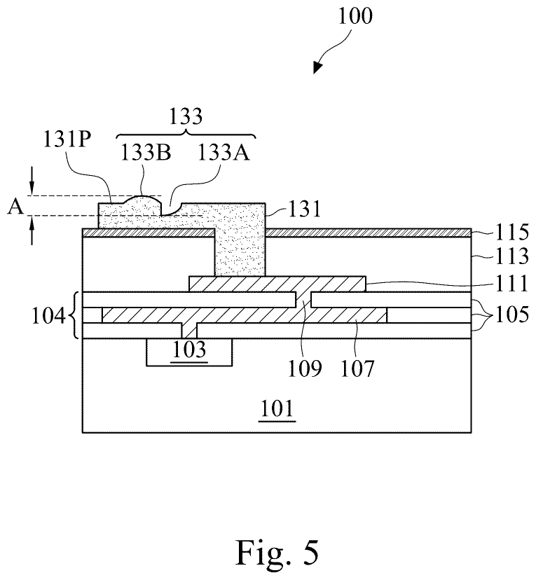

FIG. 5 shows the die 100 after the wafer testing. As illustrated in FIG. 5, a probe mark 133 is formed on the upper surface of the sacrificial pad 131P due to scratching by the probe 141. The probe mark 133 may include a dent 133A and a protrusion 133B. The dent 133A may be caused by the pressure of probe 141 on the sacrificial pad 131P, and protrusion 133B may be caused by a portion of the solder material being pushed away from its original location by the probe 141. The depth A of the probe mark 133, measured as the peak-to-valley distance of the probe mark 133, is larger than 2 μm, in some embodiments.

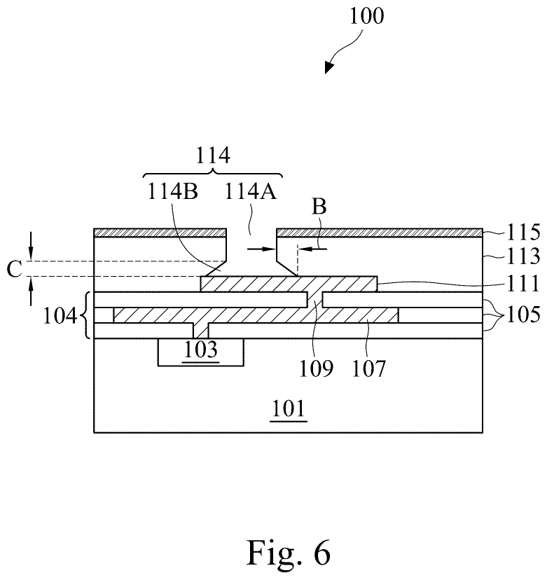

Next, in FIG. 6, the sacrificial test structures 131 are removed. In some embodiments, a wet etch process is performed to remove the sacrificial test structures 131. The wet etch process may be performed using an etchant comprising H₂SO₄ and Fe₂(SO₄)₃, as an example. In the example of FIG. 6, the wet etch process not only removes the sacrificial test structures 131 to form openings 114A in the passivation layer 113, but also removes portions of the passivation layer 113 proximate to (e.g. contacting) the conductive pads 111 to form undercuts 114B at the bottoms of the openings 114A. Each opening 114A (e.g., which has straight sidewalls extending perpendicular to the upper surface of the substrate 101) and the corresponding undercut 114B are collectively referred to as an opening 114. A width B of the undercut 114B may be larger than 0.01 μm. A height C of the undercut 114B may be 1 μm or less.

In the example of FIG. 6, each opening 114 has an upper portion with parallel sidewalls, and has a lower portion with sidewalls that extend away from each other along the depth direction of the opening 114. In other words, the upper portion of the opening 114 has a substantially uniform width, and the lower portion of the opening 114 has a width that increases along the depth direction. Note that the location of the opening 114A corresponds to (e.g., is the same as) the location of the opening 112 in FIG. 2.

Since the probe 141 does not contact the conductive pad 111, no probe mark is formed on the conductive pad 111. Therefore, the upper surface of the conductive pad 111 is considered flat within the limitation of the manufacturing process. For example, the vertical distance between a highest point and a lowest point of the upper surface of the conductive pad 111 is smaller than 2 μm, such as smaller than 1 μm, or 0.5 μm.

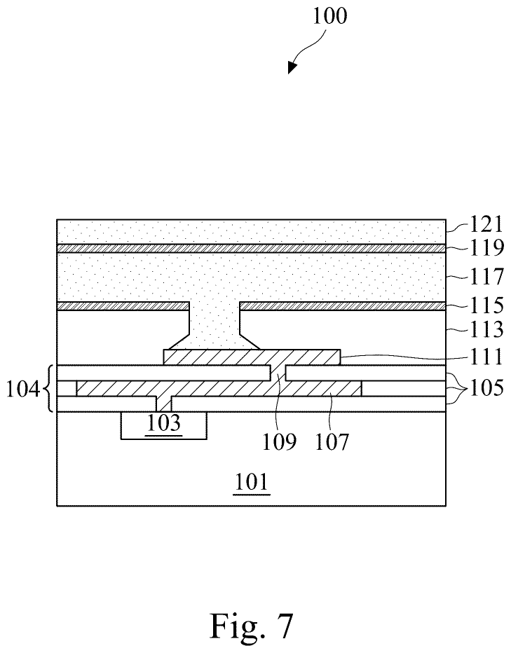

Next, in FIG. 7, a dielectric layer 117 is formed over the ESL 115. The dielectric layer 117 also fills the openings 114. The dielectric layer 117 may be formed using a suitable dielectric material such as silicon oxide by a suitable formation method, such as CVD. A planarization process, such as CMP, may be performed to achieve a planar upper surface for the dielectric layer 117. Since the dielectric layer 117 fills the openings 114, the dielectric layer 117 inside each opening 114 has an upper portion with a substantially uniform width, and has a lower portion with a width that increases along the depth direction of the dielectric layer 117, in some embodiments.

Next, an ESL 119 is formed over the dielectric layer 117. In some embodiments, the ESL 119 is formed of a suitable material such as silicon nitride (e.g., SiN), silicon carbide (e.g., SiC), silicon carbonitride (e.g., SiCN), silicon oxynitride (SiON), or the like, and may be formed by a suitable formation method, such as physical vapor deposition (PVD), CVD, plasma-enhanced CVD (PECVD), or the like. The ESL 119 is used to protect the underlying structures and may be used to provide a control point for a subsequent etching process, in some embodiments.

Next, a dielectric layer 121 is formed over the ESL 119. The dielectric layer 121 may be formed using a suitable dielectric material such as silicon oxide by a suitable formation method, such as CVD. A planarization process, such as CMP, may be performed to achieve a planar upper surface for the dielectric layer 121.

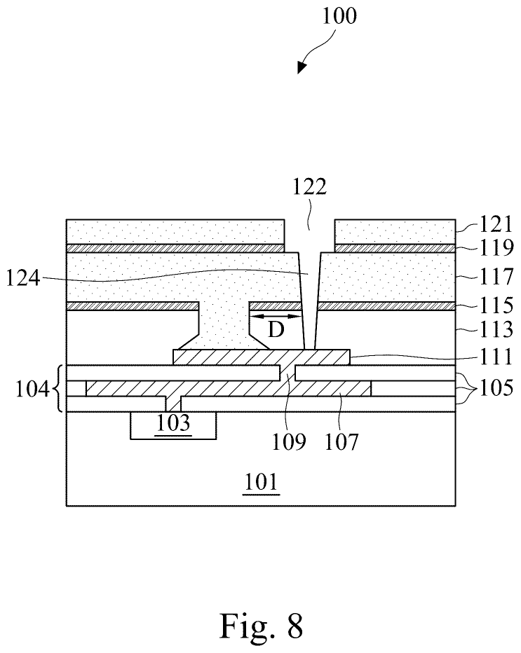

Next, FIG. 8, pad openings 122 and via openings 124 are formed. The pad opening 122 are formed to extend through the dielectric layer 121 and the ESL 119, and are filled by conductive material(s) subsequently to form bonding pads. The via openings 124 are formed under the pad openings 122 to extend through the dielectric layer 117, through the ESL 115, and into the passivation layer 113 to expose the underlying conductive pads 111. The via openings 124 are filled by conductive material(s) subsequently to form vias. In some embodiments, the pad openings 122 are formed first (e.g., before the via openings 124) in the dielectric layer 121 and the ESL 119 to expose the dielectric layer 117 by a first patterning process. After the pad openings 122 are formed, the via openings 124 are formed in the dielectric layer 117, the ESL 115, and the passivation layer 113 to expose the conductive pads 111 by a second patterning process.

In the example of FIG. 8, each via opening 124 is formed to be laterally adjacent to (e.g., spaced apart from) the location of a respective openings 114 (see FIG. 6). In some embodiments, a distance D between the via opening 124 and the respective opening 114 is larger than 2 μm. In some embodiments, portions of the passivation layer 113 above and around the undercuts 114B have lower structural integrity. The distance D ensures that the via openings 144 (and the vias formed subsequently) are not formed in those portions of the passivation layer 113 with lower structural integrity.

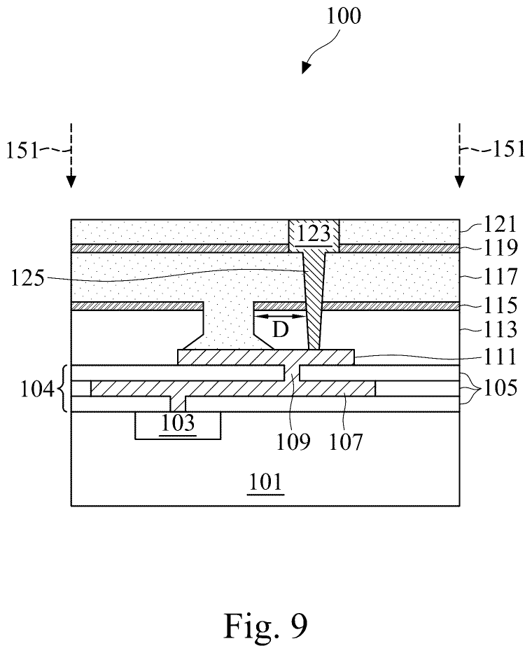

Next, in FIG. 9, conductive material(s) are formed in the via openings 124 and the pad openings 122 to form vias 125 and bonding pads 123, respectively.

In some embodiments, a barrier layer is formed to line sidewalls of the pad openings 122 and to line sidewalls and bottoms of the via openings 124 before a conductive material is formed to fill the via openings 124 and the pad openings 122. The barrier layer may comprise an electrically conductive material such as titanium nitride, although other materials, such as tantalum nitride, titanium, tantalum, or the like, may alternatively be utilized. The barrier layer may be formed using a CVD process, such as plasma-enhanced CVD (PECVD). However, other alternative processes, such as sputtering or metal organic chemical vapor deposition (MOCVD), atomic layer deposition (ALD), may alternatively be used.

Next, the conductive material is formed to fill the via openings 124 and the pad openings 122. The conductive material may comprise copper, although other suitable materials such as aluminum, tungsten, alloys, combinations thereof, and the like, may alternatively be utilized. The conductive material may be formed by depositing a seed layer and then electroplating the conductive material (e.g., copper) onto the seed layer, filling and overfilling the via openings 124 and the pad openings 122. Once the openings have been filled, excess barrier layer and excess conductive material outside of the openings may be removed by a planarization process, such as CMP, although any suitable removal process may be used. The remaining conducive material inside the via openings 124 and the pad openings 122 form the vias 125 and the bonding pads 123, respectively. The bonding pads 123 may also be referred to as die connectors.

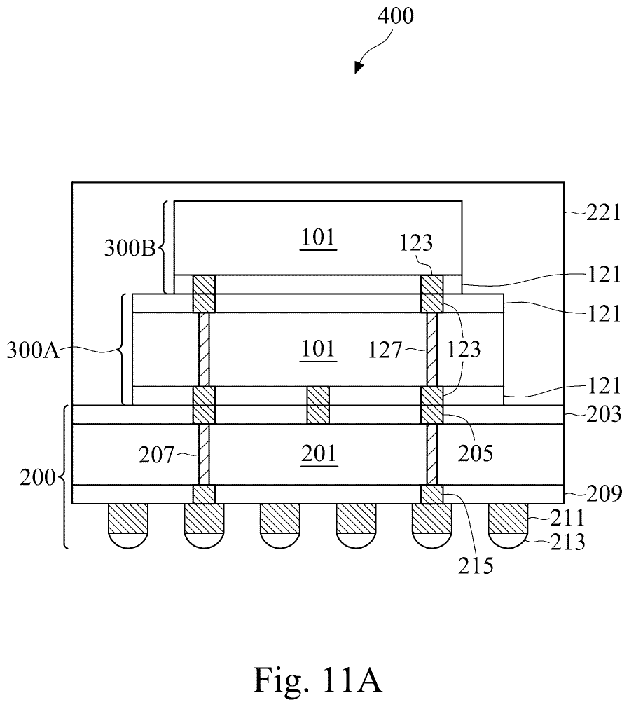

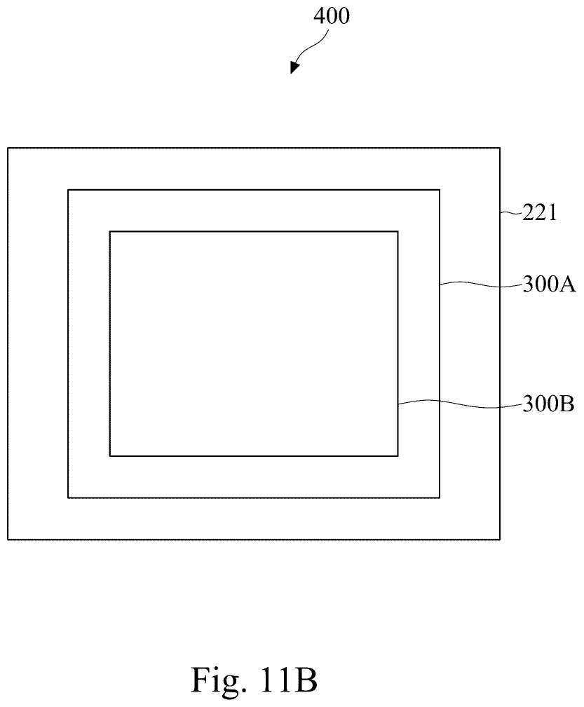

After the bonding pads 123 are formed, a dicing process may be performed along dicing regions indicated by the dashed lines 151 in FIG. 9 to separate the dies 100 formed on the wafer into separate, individual, dies 100. The dies 100 that passed wafer testing are be used to form various semiconductor devices. An example is discussed below with reference to FIGS. 11A and 11B.

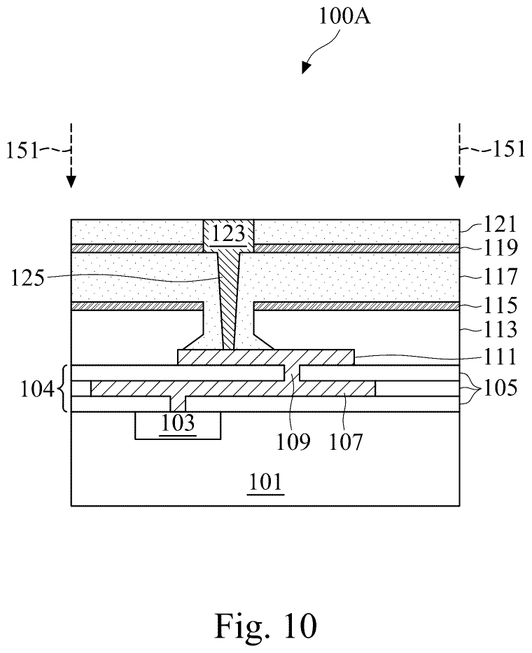

FIG. 10 illustrates a cross-sectional view of a semiconductor device 100A, in accordance with another embodiment. The semiconductor device 100A (e.g., a die 100A) is similar to the semiconductor device 100, but the vias 125 and the bonding pads 123 are formed at different locations. In particular, each via 125 is formed to extend through the portion of the dielectric layer 117 filling the opening 114. In other words, the via 125 is formed inside the opening 114. Therefore, the via 125 is spaced apart from (e.g., does not contact) the passivation layer 113 and the ESL 115. As illustrated in FIG. 10, the via 125 extends from the upper surface of the dielectric layer 117 distal from the substrate 101 to a lower surface of the dielectric layer 117 contacting the conductive pad 111. The corresponding bonding pad 123 is formed over (e.g., directly over and contacting) the via 125, and extends through the dielectric layer 121 and the ESL 119.

The embodiment of FIG. 10 achieves additional advantages. For example, since the via 125 of FIG. 10 only extends through the dielectric layer 117, the etching process for forming the via opening may be simpler than the etching process for forming the via opening 124 in FIG. 8. This is because the etching process for forming the via opening 124 in FIG. 8 needs to etch through different materials (e.g., the dielectric layer 117, the ESL 115, and the passivation layer 113), and therefore, the etching process may use more types of etchant and/or more etching steps. In addition, the portion of the dielectric layer 117 filling the opening 114 has no structural integrity issue, and therefore, the via 125 in FIG. 10 can be formed without the constraint of the minimum distance D (see FIG. 8) between the via opening and the opening 114.

FIGS. 11A and 11B illustrate a cross-sectional view and a top view, respectively, of a semiconductor structure 400, in accordance an embodiment. The semiconductor structure 400 may be, e.g., an SoIC device that is formed by bonding the know good dies to an interposer. As illustrated in FIGS. 11A and 11B, the semiconductor structure 400 includes an interposer 200, dies 300A and 300B stacked vertically over the interposer 200, and a molding material 221 on the interposer 200 around the dies 300A and 300B.

In the illustrated embodiment, the interposer 200 includes a substrate 201, through vias 207, and conductive pads 205 and 215 at the upper surface and the lower surfaces of the substrate 201, respectively. FIG. 11A also illustrates passivation layers 203 and 209 of the interposer 200, which are on the upper surface and the lower surface of the substrate 201, respectively, and surround the conductive pads 205 and 215, respectively. In addition, the interposer 200 includes external connectors 211 (may also be referred to as conductive bumps) formed on the conductive pads 215. Solder regions 213 may be formed on the external connectors 211. The conductive pads 205 and 215 may also be referred to as bonding pads of the interposer 200.

The substrate 201 may be, e.g., a silicon substrate, doped or undoped, or an active layer of a silicon-on-insulator (SOI) substrate. However, the substrate 201 may alternatively be a glass substrate, a ceramic substrate, a polymer substrate, or any other substrate that may provide a suitable protection and/or interconnection functionality.

In some embodiments, the substrate 201 may include electrical components, such as resistors, capacitors, combinations of these, or the like. These electrical components may be active, passive, or a combination thereof. In other embodiments, the substrate 201 is free from both active and passive electrical components therein. All such combinations are fully intended to be included within the scope of this disclosure.

Through vias 207 extend from the upper surface of the substrate 201 to the lower surface of the substrate 201, and provide electrical connections between the conductive pads 205 and 215. The through vias 207 may be formed of a suitable conductive material such as copper, tungsten, aluminum, alloys, combinations thereof, and the like. A barrier layer may be formed between the through vias 207 and the substrate 201. The barrier layer may comprise a suitable material such as titanium nitride, although other materials, such as tantalum nitride, titanium, or the like, may alternatively be utilized.

Although not illustrated, a redistribution structure (RDS) may be formed on the upper surface of the substrate 201 between the substrate 201 and the passivation layer 203. The RDS structure is electrically coupled to the through vias 207 and the conductive pads 205, and reroutes electrical signals along the upper surface of the substrate 201. The RDS may include one or more dielectric layers (e.g., silicon oxide) and conductive features (e.g., conductive lines and vias) formed in the one or more dielectric layers. In addition, another RDS may be formed on the lower surface of the substrate 201 between the substrate 201 and the passivation layer 209.

The passivation layers 203 and 209 may be formed of a suitable material, such as silicon oxide, silicon nitride, combinations thereof, or the like. In some embodiments, a polymer material, such as polyimide, may be used to form the passivation layers 203 and 209. A suitable formation method, such as CVD, PECVD, spin coating, or the like, may be performed to form the passivation layers 203 and 209.

The external connectors 211 are formed on the conductive pads 215, and extend through the passivation layers 209 to be electrically coupled to the conductive pads 215. The external connectors 211 may be any suitable type of external contacts, such as microbumps, copper pillars, a copper layer, a nickel layer, a lead free (LF) layer, an electroless nickel electroless palladium immersion gold (ENEPIG) layer, a Cu/LF layer, a Sn/Ag layer, a Sn/Pb, combinations of these, or the like.

The dies 300A and 300B may be the same as or similar to the die 100, and are known good dies (KGDs) that passed the wafer testing. For simplicity, not all features of the die 100 in FIG. 9 or FIG. 10 are illustrated for the dies 300A and 300B in FIG. 11A. For example, the die 300B in FIG. 11A only illustrates the substrates 101, the bonding pads 123, and the dielectric layer 121. Note that the die 300A has bonding pads 123 and dielectric layers 121 on both the upper side and the lower side of the substrate 101, and further includes through-substrate-vias (TSVs) 127 that electrically couples the bonding pads 123 on the upper side and the lower side of the substrate 101.

In some embodiments, the die 300A is bonded to the conductive pads 205 of the interposer 200 through direct bonding (e.g., direct metal-to-metal bonding, direct dielectric-to-dielectric bonding) without using an adhesive material (e.g., solder). The direct bonding process may include cleaning the surfaces of the die 300A and the interposer 200, aligning the bonding pads 123 of the die 300A with respective conductive pads 205 of the interposer 200, and pressing the die 300A and the interposer 200 together. A heat treatment may be performed to facilitate the directing bonding process. The resulting bonds between the die 300A and the interposer 200 include both dielectric-to-dielectric bonds (e.g., dielectric layers 121 to passivation layer 203) and metal-to-metal bonds (e.g., bonding pads 123 to conductive pads 205). Similarly, the die 300B may be bonded to the bonding pads 123 at the upper side of the die 300A through direct bonding. In other embodiments, the dies 300A and 300B are bonded using a solder material.

Next, the molding material 221 is formed on the interposer 200 around the dies 300A and 300B. The molding material 221 may comprise an epoxy, an organic polymer, a polymer with or without a silica-based filler or glass filler added, or other materials, as examples. In some embodiments, the molding material 221 comprises a liquid molding compound (LMC) that is a gel type liquid when applied. The molding material 221 may also comprise a liquid or solid when applied. Alternatively, the molding material 221 may comprise other insulating and/or encapsulating materials. The molding material 221 is applied using a wafer level molding process in some embodiments. The molding material 221 may be molded using, for example, compressive molding, transfer molding, molded underfill (MUF), or other methods.

Next, the molding material 221 is cured using a curing process, in some embodiments. The curing process may comprise heating the molding material 221 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 221 may be cured using other methods. In some embodiments, a curing process is not included.

After the molding material 221 is formed, a planarization process, such as CMP, may be performed to achieve a planar upper surface for the molding material 221. In the illustrated embodiments, the molding material 221 extends further from the interposer 200 than the dies 300A and 300B, thus covering the upper surface of the die 300B. In some embodiments, the molding material 221 and the die 300B have a coplanar upper surface. Sidewalls of the molding material 221 are aligned with respective sidewalls of the interposer 200 along the same vertical lines, in the illustrated embodiment.

Embodiments may achieve advantages. For example, the disclosed sacrificial test structure 131 prevents probe marks from being formed on the conductive pads 111 of the die 100, thus preserving the flatness of the upper surface of the conductive pads 111 and reducing the risk of delamination of the dielectric layer 117. When the die 100 is used for forming other semiconductor structures (e.g., 400), the dielectric layer 117 is subject to subsequent high-temperature processes, such as the bonding process for the dies 300A/300B, and the molding process for forming the molding material 221. The high-temperature processes, together with the mismatch of the coefficients of thermal expansion (CTEs) between the molding material 221 and the dies 300A/300B, may cause high stress in the dies 300A/300B and may result in delamination of the dielectric layer 117. Delamination of the dielectric layer 117 may result in device failure of the semiconductor structure (e.g., 400). The disclosed sacrificial test structure 131, by reducing the risk of delamination, reduces device failure in the semiconductor structure (e.g., 400) and increases production yield.

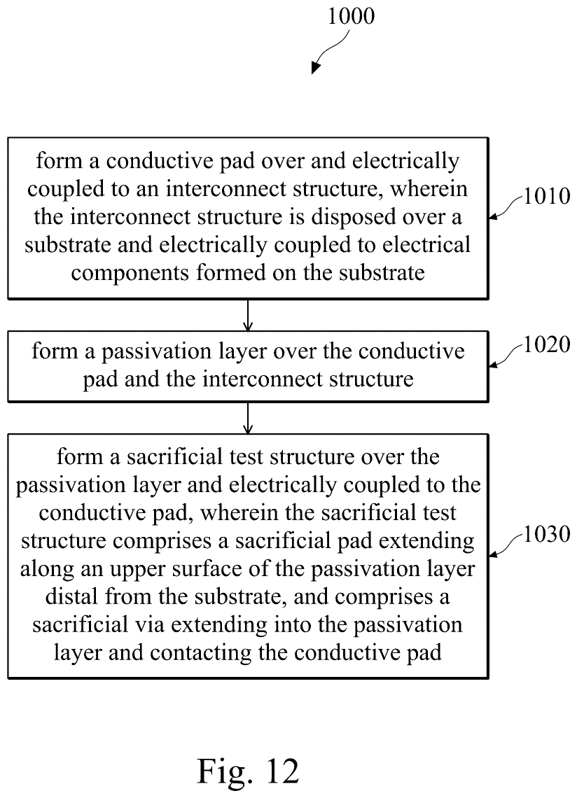

FIG. 12 illustrates a flow chart of a method 1000 of forming a semiconductor device, in some embodiments. It should be understood that the embodiment method shown in FIG. 12 is merely an example of many possible embodiment methods. One of ordinary skill in the art would recognize many variations, alternatives, and modifications. For example, various steps as illustrated in FIG. 12 may be added, removed, replaced, rearranged and repeated.

Referring to FIG. 12, at block 1010, a conductive pad is formed over and electrically coupled to an interconnect structure, wherein the interconnect structure is disposed over a substrate and electrically coupled to electrical components formed on the substrate. At block 1020, a passivation layer is formed over the conductive pad and the interconnect structure. At block 1030, a sacrificial test structure is formed over the passivation layer and electrically coupled to the conductive pad, wherein the sacrificial test structure comprises a sacrificial pad extending along an upper surface of the passivation layer distal from the substrate, and comprises a sacrificial via extending into the passivation layer and contacting the conductive pad.

In accordance with an embodiment, a method of forming a semiconductor device includes: forming a conductive pad over and electrically coupled to an interconnect structure, wherein the interconnect structure is disposed over a substrate and electrically coupled to electrical components formed on the substrate; forming a passivation layer over the conductive pad and the interconnect structure; and forming a sacrificial test structure over the passivation layer and electrically coupled to the conductive pad, wherein the sacrificial test structure comprises a sacrificial pad extending along an upper surface of the passivation layer distal from the substrate, and comprises a sacrificial via extending into the passivation layer and contacting the conductive pad. In an embodiment, the method further comprises: probing the sacrificial pad with a probe; after the probing, removing the sacrificial test structure, where removing the sacrificial test structure forms a first opening in the passivation layer; forming a first dielectric layer over the passivation layer, wherein a first portion of the first dielectric layer fills the first opening; forming a second dielectric layer over the first dielectric layer; forming a via that extends through the first dielectric layer and electrically couples to the conductive pad; and forming a bonding pad that extends through the second dielectric layer and electrically couples to the via. In an embodiment, forming the sacrificial test structure comprises: forming a second opening in the passivation layer to expose the conductive pad; depositing a solder material in the second opening and along the upper surface of the passivation layer, wherein the solder material in the second opening forms the sacrificial via; and patterning the solder material disposed along the upper surface of the passivation layer, wherein after the patterning, a remaining portion of the solder material along the upper surface of the passivation layer forms the sacrificial pad. In an embodiment, in a top view, the sacrificial pad has a larger area than the sacrificial via. In an embodiment, removing the sacrificial test structure comprises performing a wet etch process. In an embodiment, the wet etch process removes the solder material in the second opening, wherein the wet etch process further removes a portion of the passivation layer contacting the conductive pad to form an undercut under the passivation layer. In an embodiment, the conductive pad is formed of a first conductive material, wherein the via and the bonding pad are formed of a second conductive material different from the first conductive material. In an embodiment, the first conductive material is aluminum, and the second conductive material is copper. In an embodiment, the via is spaced apart from the first portion of the first dielectric layer. In an embodiment, an upper portion of the via extends through the first dielectric layer, and a lower portion of the via extends into the passivation layer and contacts the conductive pad. In an embodiment, the via is formed to be embedded in the first portion of the first dielectric layer.

In accordance with an embodiment, a method of forming a semiconductor device includes: forming a conductive pad over and electrically coupled to an interconnect structure, wherein the interconnect structure is formed over a substrate and electrically couples electrical components formed on the substrate to form a functional circuit; forming a passivation layer over the conductive pad and the interconnect structure; forming a sacrificial test structure that is electrically coupled to the conductive pad, wherein the sacrificial test structure is formed to include a sacrificial pad along an upper surface of the passivation layer and include a sacrificial via extending into the passivation layer and electrically coupled to the conductive pad; testing the functional circuit by probing the sacrificial pad with a probe; and removing the sacrificial test structure after the testing. In an embodiment, removing the sacrificial test structure forms an opening in the passivation layer, wherein the method further comprises, after removing the sacrificial test structure: forming a first dielectric material over the passivation layer and in the opening; forming a second dielectric material over the first dielectric material; forming a via that extends through the first dielectric material and contacts the conductive pad; and forming a bonding pad that extends through the second dielectric material and contacts the via. In an embodiment, forming the sacrificial test structure comprises: forming a recess in the passivation layer to expose the conductive pad; depositing a solder material in the recess and along the upper surface of the passivation layer; and patterning the solder material disposed along the upper surface of the passivation layer. In an embodiment, removing the sacrificial test structure comprises performing a wet etch process to remove the solder material, wherein the wet etch process further removes a portion of the passivation layer proximate to the conductive pad to form an undercut, wherein the opening includes the recess and the undercut. In an embodiment, the via is formed laterally adjacent to a location of the opening, wherein an upper portion of the via is embedded in the first dielectric material, and a lower portion of the via is embedded in the passivation layer. In an embodiment, a portion of the first dielectric material fills the opening, wherein via is formed to be embedded in the portion of the first dielectric material.

In accordance with an embodiment, a method of forming a semiconductor device includes: forming an interconnect structure over a substrate, wherein the interconnect structure connects electrical components formed on the substrate to form a functional circuit; forming a conductive pad over and electrically coupled to the interconnect structure; forming a passivation layer over the conductive pad and the interconnect structure; forming a sacrificial test structure that extends through the passivation layer and electrically couples to the conductive pad; testing the functional circuit by probing the sacrificial test structure with a probe; removing the sacrificial test structure after the testing; and after removing the sacrificial test structure, forming a via and a bonding pad that are over and electrically coupled to the conductive pad. In an embodiment, removing the sacrificial test structure forms an opening in the passivation layer, wherein forming the via and the bonding pad comprises: forming a first dielectric material in the opening and along the upper surface of the passivation layer; forming a second dielectric material over the first dielectric material; forming the via in the first dielectric material, wherein the via contacts the conductive pad; and forming the bonding pad in the second dielectric material, wherein the bonding pad is over and contacts the via. In an embodiment, forming the sacrificial test structure comprises: forming a recess in the passivation layer to expose the conductive pad; depositing a solder material in the recess and along the upper surface of the passivation layer; and patterning the solder material disposed along the upper surface of the passivation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a conductive pad over and electrically coupled to an interconnect structure, wherein the interconnect structure is disposed over a substrate and electrically coupled to electrical components formed on the substrate;
forming a passivation layer over the conductive pad and the interconnect structure; and
forming a sacrificial test structure over the passivation layer and electrically coupled to the conductive pad, wherein the sacrificial test structure comprises a sacrificial pad extending along an upper surface of the passivation layer distal from the substrate, and comprises a sacrificial via extending into the passivation layer and contacting the conductive pad.

2. The method of claim 1, further comprising:
probing the sacrificial pad with a probe;
after the probing, removing the sacrificial test structure, where removing the sacrificial test structure forms a first opening in the passivation layer;
forming a first dielectric layer over the passivation layer, wherein a first portion of the first dielectric layer fills the first opening;
forming a second dielectric layer over the first dielectric layer;
forming a via that extends through the first dielectric layer and electrically couples to the conductive pad; and
forming a bonding pad that extends through the second dielectric layer and electrically couples to the via.

3. The method of claim 2, wherein forming the sacrificial test structure comprises:
forming a second opening in the passivation layer to expose the conductive pad;
depositing a solder material in the second opening and along the upper surface of the passivation layer, wherein the solder material in the second opening forms the sacrificial via; and
patterning the solder material disposed along the upper surface of the passivation layer, wherein after the patterning, a remaining portion of the solder material along the upper surface of the passivation layer forms the sacrificial pad.

4. The method of claim 3, wherein in a top view, the sacrificial pad has a larger area than the sacrificial via.

5. The method of claim 3, wherein removing the sacrificial test structure comprises performing a wet etch process.

6. The method of claim 5, wherein the wet etch process removes the solder material in the second opening, wherein the wet etch process further removes a portion of the passivation layer contacting the conductive pad to form an undercut under the passivation layer.

7. The method of claim 2, wherein the conductive pad is formed of a first conductive material, wherein the via and the bonding pad are formed of a second conductive material different from the first conductive material.

8. The method of claim 7, wherein the first conductive material is aluminum, and the second conductive material is copper.

9. The method of claim 2, wherein the via is spaced apart from the first portion of the first dielectric layer.

10. The method of claim 9, wherein an upper portion of the via extends through the first dielectric layer, and a lower portion of the via extends into the passivation layer and contacts the conductive pad.

11. The method of claim 2, wherein the via is formed to be embedded in the first portion of the first dielectric layer.

12. A method of forming a semiconductor device, the method comprising:
forming a conductive pad over and electrically coupled to an interconnect structure, wherein the interconnect structure is formed over a substrate and electrically couples electrical components formed on the substrate to form a functional circuit;
forming a passivation layer over the conductive pad and the interconnect structure;
forming a sacrificial test structure that is electrically coupled to the conductive pad, wherein the sacrificial test structure is formed to include a sacrificial pad along an upper surface of the passivation layer and include a sacrificial via extending into the passivation layer and electrically coupled to the conductive pad;
testing the functional circuit by probing the sacrificial pad with a probe; and
removing the sacrificial test structure after the testing.

13. The method of claim 12, wherein removing the sacrificial test structure forms an opening in the passivation layer, wherein the method further comprises, after removing the sacrificial test structure:
forming a first dielectric material over the passivation layer and in the opening;
forming a second dielectric material over the first dielectric material;
forming a via that extends through the first dielectric material and contacts the conductive pad; and
forming a bonding pad that extends through the second dielectric material and contacts the via.

14. The method of claim 13, wherein forming the sacrificial test structure comprises:
forming a recess in the passivation layer to expose the conductive pad;
depositing a solder material in the recess and along the upper surface of the passivation layer; and
patterning the solder material disposed along the upper surface of the passivation layer.

15. The method of claim 14, wherein removing the sacrificial test structure comprises performing a wet etch process to remove the solder material, wherein the wet etch process further removes a portion of the passivation layer proximate to the conductive pad to form an undercut, wherein the opening includes the recess and the undercut.

16. The method of claim 13, wherein the via is formed laterally adjacent to a location of the opening, wherein an upper portion of the via is embedded in the first dielectric material, and a lower portion of the via is embedded in the passivation layer.

17. The method of claim 13, wherein a portion of the first dielectric material fills the opening, wherein via is formed to be embedded in the portion of the first dielectric material.

18. A method of forming a semiconductor device, the method comprising:
forming an interconnect structure over a substrate, wherein the interconnect structure connects electrical components formed on the substrate to form a functional circuit;
forming a conductive pad over and electrically coupled to the interconnect structure;
forming a passivation layer over the conductive pad and the interconnect structure;
forming a sacrificial test structure that extends through the passivation layer and electrically couples to the conductive pad;
testing the functional circuit by probing the sacrificial test structure with a probe;
removing the sacrificial test structure after the testing; and
after removing the sacrificial test structure, forming a via and a bonding pad that are over and electrically coupled to the conductive pad.

19. The method of claim 18, wherein removing the sacrificial test structure forms an opening in the passivation layer, wherein forming the via and the bonding pad comprises:
forming a first dielectric material in the opening and along the upper surface of the passivation layer;
forming a second dielectric material over the first dielectric material;
forming the via in the first dielectric material, wherein the via contacts the conductive pad; and
forming the bonding pad in the second dielectric material, wherein the bonding pad is over and contacts the via.

20. The method of claim 18, wherein forming the sacrificial test structure comprises:
forming a recess in the passivation layer to expose the conductive pad;
depositing a solder material in the recess and along the upper surface of the passivation layer; and
patterning the solder material disposed along the upper surface of the passivation layer.
